(19) United States
(12) Patent Application Publication
(10) Pub. No.: US 2011/0220185 A1
(43) Pub. Date: Sep. 15, 2011

(54) METHOD OF MANUFACTURING A PHOTOVOLTAIC MODULE

(75) Inventors: Ivan Sinicco, Pfaffikon (CH); Andreas Huegli, Seewis (CH)

(73) Assignee: OERLIKON SOLAR AG, TRUBBACH, Trubbach (CH)

(21) Appl. No.: 13/120,100

(22) PCT Filed: Sep. 23, 2009
(86) PCT No.: PCT/EP09/62331

§ 371 Date: May 26, 2011

Related U.S. Application Data
(60) Provisional application No. 61/099,337, filed on Sep. 23, 2008.

(51) Int. Cl. H01L 31/048; H01L 31/0224; H01L 31/18

(52) U.S. Cl. 136/251; 136/256; 438/65; 257/E31.117

(57) ABSTRACT

The invention relates to a method of manufacturing a photovoltaic module comprising the following steps: a) assembling a front end part (10) comprising a front cover element and a photovoltaic cell, b) assembling a back end part (12) comprising a back reflector, a junction box and a back cover element, and c) connecting the assembled front end part (10) with the assembled back end part (12). Further, the invention relates to an assembled back end part (12) and to an interlayer foil (14).

### TECHNICAL FIELD

The invention relates to a method of manufacturing a photovoltaic module. Further, the invention relates to an assembled back end part and to an interlayer foil.

### BACKGROUND ART

It has long been desirable to capture radiation, particularly visible light, to convert it directly into electrical energy through the utilization of photovoltaic cells. Many types of photovoltaic cells, often referred to as solar cells, have been considered and constructed. For example, single-crystal cells have been produced, as well as those produced from gallium arsenide and other similar materials. In addition, thin film cells have been fabricated from microcrystalline, amorphous, compound or semiconductor material other than single crystal semiconductor material, deposited in situ upon a substrate by chemical vapor deposition, sputtering or other similar means. In use, these cells are assembled in photovoltaic panels and modules which must withstand the rigors of the environment and handling in commerce.

As used herein, the term photovoltaic panel refers to a combination of a sheet of transparent material or other lamina called front cover element, an array or group of photovoltaic cells interconnected to provide a desirable power output, and any backing sheet or material called back cover element, which forms a device capable of transforming incident radiation to electrical current in a reliable way. Such panels are traditionally comprised of a transparent front or radiation-facing sheet such as a glass or transparent polymer, laminated with layers of transparent conductors, photovoltaic materials, cell-connecting circuits, metals and other lamina which together comprise an operative photovoltaic panel. Thus, photovoltaic panels have traditionally included a sheet of glass or other rigid transparent material to protect the photovoltaic cell, and a back sheet of glass, also called back glass, or a polymeric laminate that can comprise an aluminum foil, with the various laminas being bonded together by a dielectric layer of plasticized polyvinyl butyral, ethylene vinyl acetate, olefin based interlayer materials or other compounds known by the skilled in the field.

Depending on the interlayer foil used, the initial assembly of the laminates which comprise the photovoltaic panel, the edges of the panel can be smoothed to provide a flush edge surface, and sealed with a non-conductive varnish followed by one or more layers of polyester and/or polyurethane tape or butyl tape. After this sealing of the edges, the panel is enclosed in a peripheral frame of aluminum, steel, molded polymer or other rigid frame material. This method of sealing and framing the periphery of the panel has been necessary to isolate the solar cell from the environment, and to provide a frame for the strengthening of the panel and to provide a border to permit ease of handling and the attachment of connector boxes and the like for attachment of the photovoltaic cell to an external electrical circuit. For example, a solar panel with a hardened foil back layer sandwiched between polyvinyl fluoride resin sheets, and framed in rigid peripheral framing is shown in U.S. Pat. No. 4,401,839. This combination of a photovoltaic panel with the frame, sealing means, connection means and ancillary supporting structures is referred to herein as a photovoltaic module.

U.S. Pat. No. 5,008,062 A describes a photovoltaic panel that is supported, sealed and isolated from the environment by being encased in a reaction injection molded elastomer which encapsulates the back, sides and a portion of the front side of the photovoltaic panel.

WO 2007/011580 A2 describes a photovoltaic module comprising a first superstrate, a back sheet, a photovoltaic cell or a plurality of photovoltaic cells, each photovoltaic cell encapsulated and positioned between the superstrate and the back sheet, where the back sheet comprises a polyester material.

When fabricating such a photovoltaic module, the respective sheets, layers and elements of the photovoltaic panel or photovoltaic module are separately arranged on each other in the right order like forming a sandwich structure, which causes a very time consuming manufacturing with high production costs. For example, after applying a photovoltaic cell on a front cover element, contacting elements are applied on the front cover element comprising the photovoltaic cell, a back reflector is applied on the contacting elements, a lamination layer is applied on the back reflector and a junction box is applied on the lamination layer.

### DISCLOSURE OF INVENTION

It is an object of the invention to provide a method of manufacturing a photovoltaic module, a back end part of a photovoltaic module and an interlayer foil being able of reducing the time of manufacturing a photovoltaic module together with a reduction of the manufacturing costs.

The solution of the object is achieved by the features of the independent claims. Preferred embodiments are given by the dependent claims.

The method of manufacturing a photovoltaic module according to the invention comprises the following steps of a) assembling a front end part comprising a front cover element and a photovoltaic cell, b) assembling a back end part comprising a back reflector, a junction box and a back cover element eventually comprising a mounting element for the fixation of the photovoltaic module, and c) connecting the assembled front end part with the assembled back end part.

The inventive method comprises that the front end part and the back end part are previously assembled separately before they are connected with each other to a photovoltaic panel or photovoltaic module. Thus, the back end part can be assembled parallel to the front end part which allows a high reduction of manufacturing time and manufacturing costs. The front end part of a photovoltaic module preferably comprises a front cover element, a photovoltaic cell and if more than one photovoltaic cells are provided an interconnection between the photovoltaic cells is added to the front end part. The photovoltaic cell is preferably a thin film photovoltaic cell capable of converting radiation to electrical energy. The front end part is assembled by putting the photovoltaic cell on the front cover element. The front cover element may be a transparent material, like a glass. Preferably at the same time the back end part of the photovoltaic module is assembled, wherein at least a back reflector, a junction box and a back cover element are connected with each other. The back cover element may comprise a supporting structure on an integrated back glass or structure. Thus, all components necessary for the back end part of the photovoltaic module are preassembled before being connected with the elements of the front end part of the photovoltaic module. The front end part connected with the back end part form a photovoltaic panel, wherein after framing this photovoltaic panel a photovoltaic module is formed. The mounting element may comprise a holder, a stand and/or a wall fixing means.

According to a preferred embodiment of the invention, electrical contacting elements are included into the back end part in step b). The electrical contacting elements are necessary for providing an electrical connection between the photovoltaic cell in the front end part and the back end part for transporting the electrical energy from the photovoltaic cell to the outside of the photovoltaic module, preferably via the junction box in the back end part. According to this embodiment, these electrical contacting elements are directly included into the back end part when assembling the back end part before connecting the back end part with the front end part. Since the electrical contacting elements are already inserted into the back end part when connecting the back end part with the front end part preferably no other elements need to be inserted when connecting the back end part with the front end part. This enables are very easy and fast connecting between the front end part and the back end part. Further, this enables a simplification of a later recycling of the photovoltaic module and possible post repairs of the photovoltaic module are easy to realize.

When electrical contacting elements are included into the back end part in step b) it is preferred that an edge sealing material is added when connecting the assembled front end part with the assembled back end part in step c). The edge sealing material may be an edge isolation barrier. By applying this edge sealing material it is possible to avoid moisture or any other aggressive components to enter the photovoltaic module or photovoltaic panel, especially to reach the photovoltaic cell or other sensible components of the photovoltaic module or photovoltaic panel. The edge sealing material, e.g. a Butyl based material, is preferably applied on the contact surfaces between the front end part and the back end part along the peripheral area of the back end part and the front end part.

Alternative to the embodiment of including electrical contacting elements to the back end part before connecting the back end part with the front end part it is preferred according to a further embodiment that an interlayer foil comprising electrical contacting elements is arranged between the assembled front end part and the assembled back end part in step c). Thus, the electrical contacting elements are included into the interlayer foil and not in the back end part. The contacting elements are preferably metal wirings, i.e. copper wires with a SnAg coating, so that a contacting in predetermined points within the interlayer foil is possible. When connecting the back end part with the front end part the interlayer foil together with the included electrical contacting elements is arranged between the front end part and back end part. Thus, the interlayer foil contains the functional elements to permit an electrical contacting between the front end part and the preassembled back end part. Hence, it is possible to realize an electrical connection between the photovoltaic cell of the front end part and the cabling in the back end part for transporting the electrical of the photovoltaic cell to the outside of the photovoltaic module through the junction box and/or external cables and at the same time being able to protect the photovoltaic cell in the front cover element against aggressive chemical components that can be found in the environment. Thus, an outdoor protection for the photovoltaic module is provided. It is further preferred that a bi-adhesive contacting element is applied directly over the interlayer foil. In such case, the interlayer foil is comprised by a lamination foil, for example an ionomer or an olefin based material, laminated together with a backsheet, which gives appropriate electrical insulation, moisture barrier and environmental protection to the back part of the photovoltaic module and the bi-adhesive conductive tape.

Preferably, the interlayer foil is laminated between the assembled front end part and the assembled back end part. Thus, the interlayer foil is preferably bonded with the front end part and the back end part preferably by applying heat and/or pressure to the interlayer foil. To realize this the interlayer foil provides preferably one or more sealing layers. The interlayer foil may act as a bonding material to connect the front end part with the back end part without the need of further bonding materials. Thus, the manufacturing of a photovoltaic module may be simplified compared to known methods. For laminating the interlayer foil between the assembled front end part and the assembled back end part known lamination methods are preferably used.

Further it is preferred to add a reinforcing material to the back end part. The reinforcing material is preferably a metal material, fibrous material, polymeric sheets or girders which may be included within the back end part to enhance the mechanical stability of the photovoltaic panel or photovoltaic module.

The interlayer foil is preferably made of a polyolefin based polymer and/or of an ionomer based polymer. A polyolefin is a semi-crystalline thermoplastic polymer produced from a simple olefin also called an alkene with the general formula CnH2n as a monomer. For example, polyethylene is the polyolefin produced by polymerizing the olefin ethylene. For example polyethylene (PE), polypropylene (PP), polybutylene terephthalate (PBT), polyethylene terephthalate (PET) and polyamid (PA) may be used for the polyolefin based polymer of the interlayer foil. Furthermore, it is for example possible to use an ethylene vinyl acetate (EVA) as a material for the interlayer foil. EVA is the copolymer of ethylene and vinyl acetate. The weight percent vinyl acetate usually varies from 10% to 40%, with the remainder being ethylene. EVA is a polymer that approaches elastomeric materials in softness and flexibility, yet can be processed like other thermoplastics. The material has good clarity and gloss, barrier properties, low-temperature toughness, stress-crack resistance, hot-melt adhesive water proof properties, and resistance to UV radiation. Moreover, it is possible to use polyvinyl butyral (PVB) as a material for the interlayer foil. PVB is a resin usually used for applications that require strong binding, optical clarity, adhesion to many surfaces, toughness and flexibility. It is prepared from polyvinyl alcohol by reaction with butyraldehyde.

According to a further preferred embodiment, a flowable material is applied between the assembled front end part and the assembled back end part in step c). Preferably, when connecting the front end part with the back end part a gap is formed between the front end part and the back end part, wherein the flowable material may be inserted into. The flowable material preferably comprises sealing and bonding characteristics. The flowable material, e.g. a silicon based material, may be inserted additionally to the interlayer foil or alone when the electrical contacting elements are already included into the assembled back end part and no interlayer foil is needed.

It is further preferred that a step d) is provided, wherein a casing and/or a sealing at least partially encapsulating the front end part and/or the back end part is applied. Step d) is preferably realized after step c) of the method. The casing and/or sealing may be for example realized by the interlayer foil and/or the flowable material. Therefore the interlayer foil and/or the flowable material are preferably cured to join the front end part with the back end part. Using the interlayer foil and/or the flowable material for the casing and/or the sealing a unitary boundary casing, especially a unitary elastomeric boundary casing, may be provided, which encapsulates at least partly the front end part and/or the back end part and its perimeter and/or edge areas thus forming a perimeter seal. Using only the flowable material for the casing and/or the sealing the perimeter of the front end part and/or the back end part may be sealed to avoid penetration of moisture or other detrimental reactants to the front end part and/or the back end part of the photovoltaic module.

In another aspect, the present invention is directed to an assembled back end part for a photovoltaic module comprising at least one contact area providing an electrical connection between the assembled back end part and an assembled front end part. The contact areas permit to configure the front end part, especially the photovoltaic cell of the front end part, into several electrical configurations, i. e. parallel or in series, according to the needs of the appliances. This assembled back end part comprises all necessary components of a back end part of a photovoltaic module for connecting it with the front end part of the photovoltaic module. By preassembling the back end part before connecting with the front end part the manufacturing process reaches a higher efficiency.

The preferred embodiments and advantages of the assembled back end part according to the invention correspond to those described for the method of the invention above.

It is a preferred embodiment that the assembled back end part comprises electrical contacting elements to transfer generated electrical energy from the front end part to the outside of the photovoltaic module, said electrical contacting elements comprising at least one of the following elements: one or more diodes, polarity cables and respective connectors, contact stripes or areas, reflective surfaces to increase light trapping and module supporting structures.

In another aspect, the present invention is directed to an interlayer foil being arrangeable between a back end part and a front end part of a photovoltaic module comprising electrical contacting elements. Preferably, the interlayer foil is made of an olefin based polymer.

The preferred embodiments and advantages of the interlayer foil according to the invention correspond to those described for the method of the invention above.

### BRIEF DESCRIPTION OF DRAWINGS

These and other aspects of the invention will be apparent from and elucidated with reference to the embodiments described hereinafter.

In the drawings:

FIG. 1 shows a schematic view of a photovoltaic module according to a first embodiment of the invention;

FIG. 2 shows a schematic view of a photovoltaic module according to a second embodiment of the invention;

FIG. 3 shows a schematic view of an interlayer according to a first embodiment of the invention; and

FIG. 4 shows a schematic view of an interlayer according to a second embodiment of the invention.

### DETAILED DESCRIPTION OF DRAWINGS

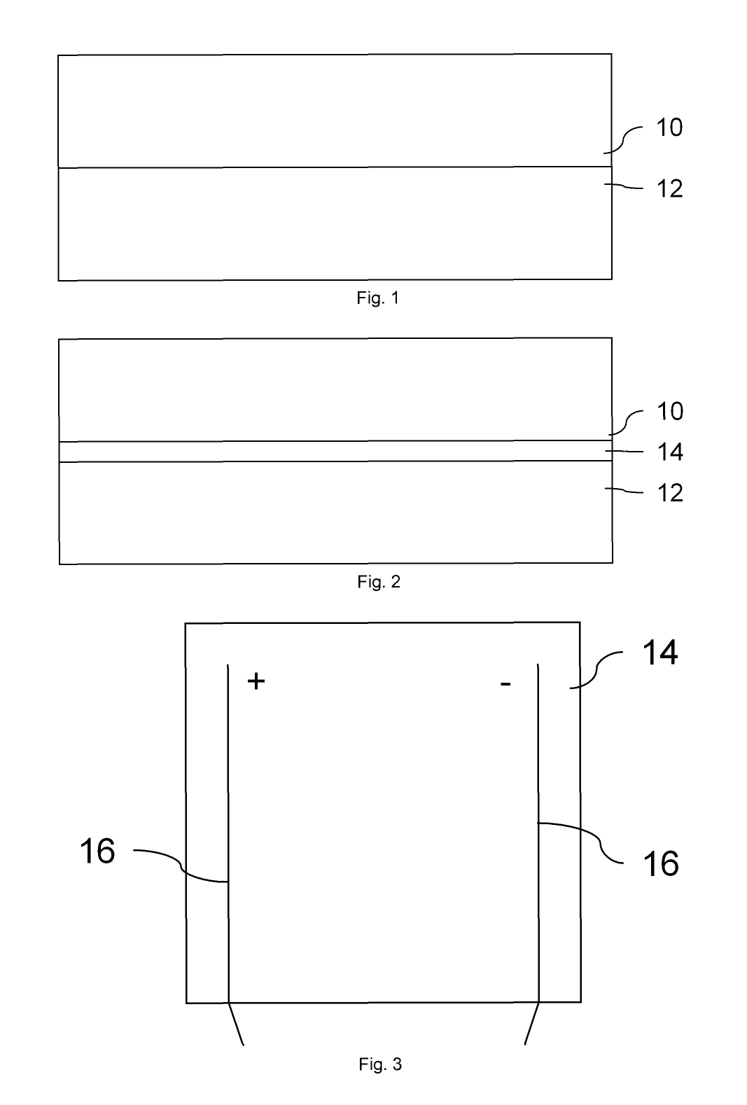

FIG. 1 shows a schematic view of a photovoltaic module according to a first embodiment of the invention comprising a front end part 10 and a back end part 12 which are connected to a photovoltaic module. The front end part 10 and the back end part 12 are previously assembled separately before they are connected with each other to a photovoltaic panel or photovoltaic module. The front end part 10 of a photovoltaic module preferably comprises a front cover element, a photovoltaic cell and an interconnection. The photovoltaic cell is preferably a thin film photovoltaic cell capable of converting radiation to electrical energy. The front end part 10 is assembled by putting the photovoltaic cell on the front cover element. The front cover element may be a transparent material, like a glass. Preferably at the same time the back end part 12 of the photovoltaic module is assembled, wherein at least a back reflector, a junction box and a back cover element are connected with each other. The back cover element may comprise a supporting structure on an integrated back glass or structure. Thus, all components necessary for the back end part 12 of the photovoltaic module are preassembled before being connected with the elements of the front end part 10 of the photovoltaic module.

According to the first shown embodiment electrical contacting elements (not shown) are included into the back end part when assembling the back end part 12. The electrical contacting elements are necessary for providing an electrical connection between the photovoltaic cell in the front end part and the back end part for transporting the electrical energy from the photovoltaic cell to the outside of the photovoltaic module, preferably via the junction box in the back end part. According to the embodiment the electrical contacting elements are directly included into the back end part 12 when assembling the back end part 12 before connecting the back end part 12 with the front end part 10. This embodiment permits to enhance flexibility of a photovoltaic module production line by offering to vary photovoltaic panels or photovoltaic modules designs just by changing the level of integration of contacting elements contained by the back end part 12.

FIG. 2 shows a second embodiment, wherein a interlayer foil 16 comprising contacting elements is placed between the front end part 10 and the back end part 12 when connecting the front end part 10 with the back end part 12. Thus, the electrical contacting elements are included into the interlayer foil 14 and not in the back end part 12. This embodiment permits to enhance flexibility of the photovoltaic module design, i. e. by changing the output voltage, just by changing the wiring in the interlayer foil 14 or by changing the cabling configuration on the back end part 12.

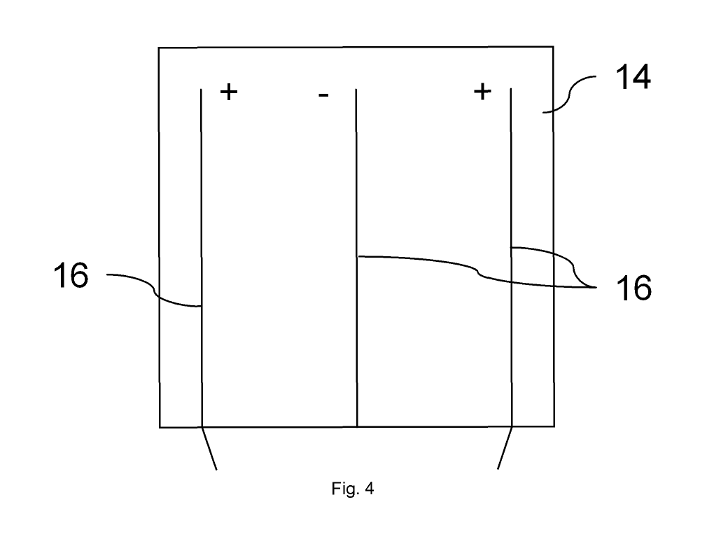

FIG. 3 and FIG. 4 show such an interlayer foil 14 comprising contacting elements 16, wherein the first embodiment of the interlayer foil 14 shown in FIG. 3 provides contacting elements 16 for a single current and the second embodiment of the interlayer foil 14 shown in FIG. 4 provides contacting elements for a double current and half voltage. For thin film photovoltaic cells, which are often intrinsically high voltage devices, a design freedom to reduce the voltage has beneficial impact at the system level cost.

While the invention has been illustrated and described in detail in the drawings and foregoing description, such illustration and description are to be considered illustrative or exemplary and not restrictive, the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1-14. (canceled)

15. Method of manufacturing a photovoltaic module comprising the following steps:
a) assembling a front end part (10) comprising a front cover element and a photovoltaic cell,
b) assembling a back end part (12) comprising a back reflector, a junction box and a back cover element eventually comprising a mounting element for the fixation of the photovoltaic module, and
c) connecting the assembled front end part (10) with the assembled back end part (12).

16. Method according to claim 15, wherein electrical contacting elements are included into the back end part (12) when assembling the back end part (12) in step b).

17. Method according to claim 16, wherein an edge sealing material is added when connecting the assembled front end part (10) with the assembled back end part (12) in step c).

18. Method according to claim 15, wherein an interlayer foil (14) comprising electrical contacting elements (16) is arranged between the assembled front end part (10) and the assembled back end part (12) in step c).

19. Method according to claim 18, wherein the interlayer foil (14) is laminated between the assembled front end part (10) and the assembled back end part (12).

20. Method according to claim 18, wherein a reinforcing material is added to the interlayer foil (14).

21. Method according to claim 18, wherein the interlayer foil (14) is made of a polyolefin based polymer and/or of an ionomer based polymer.

22. Method according to claim 15, wherein a flowable material is applied between the assembled front end part (10) and the assembled back end part (12) in step c).

23. Method according to claim 15, wherein a step d) is provided, wherein a casing and/or a sealing at least partially encapsulating the front end part (10) and/or the back end part (12) is applied.

24. Photovoltaic module comprising an assembled back end part (12) and an assembled front end part (10), wherein
the assembled front end part (10) comprises a front cover element and a photovoltaic cell,
the assembled back end part (12) comprises a back reflector, a junction box and a back cover element eventually comprises a mounting element for the fixation of the photovoltaic module, and
the assembled back end part (12) comprising at least one contact area providing an electrical connection between the assembled back end part (12) and the assembled front end part (10).

25. Photovoltaic module according to claim 24, wherein the assembled back end part (12) comprises electrical contacting elements to transfer generated electrical energy from the front end part (10) to the outside of the photovoltaic module, said electrical contacting elements comprising at least one of the following elements: one or more diodes, polarity cables and respective connectors, contact stripes or areas, reflective surfaces to increase light trapping and module supporting structures.

26. Interlayer foil being arrangeable between a back end part (12) and a front end part (10) of a photovoltaic module comprising electrical contacting elements (16), wherein
the electrical contacting elements (16) are included into the interlayer foil (14).

27. Interlayer foil according to claim 26, wherein a reinforcing material is inserted into the interlayer foil.

28. Interlayer foil according to claim 27, wherein the interlayer foil (14) is made of a polyolefin based polymer and/or of an ionomer based polymer.
